(19) United States
(12) Patent Application Publication
(10) Pub. No.: US 2024/0030099 A1
(43) Pub. Date: Jan. 25, 2024

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Chuei-Tang Wang, Taichung City (TW); Chien-Yuan Huang, Hsinchu (TW); Shih-Chang Ku, Taipei City (TW)

(73) Assignee: Taiwan Semiconductor Manufacturing Company, Ltd., Hsinchu (TW)

(21) Appl. No.: 17/868,764

(22) Filed: Jul. 19, 2022

(51) Int. Cl. H01L 23/433; H01L 23/00; H01L 21/48; H01L 21/56

(52) U.S. Cl. CPC H01L 23/4334; H01L 24/08; H01L 24/80; H01L 21/4882; H01L 21/565; H01L 25/0655

(57) ABSTRACT

Disclosed are a semiconductor structure and a manufacturing method of a semiconductor structure. In one embodiment, the semiconductor structure includes a first semiconductor element, a second semiconductor element, a heat dissipation element and a gap-filling material. The second semiconductor element is on the first semiconductor element. The heat dissipation element is on the first semiconductor element and spaced apart from the second semiconductor element by a gap. The gap-filling material is filled in the gap between the second semiconductor element and the heat dissipation element.

### BACKGROUND

A typical problem with miniaturization of semiconductor devices is heat dissipation during operation. A prolonged exposure of a die by operating at excessive temperatures may decrease the reliability and lifetime of the die. As such, improvements to heat transfer are still needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1D, FIG. 3A through FIG. 3D and FIG. 6A through FIG. 6D schematically illustrate process flows for manufacturing various semiconductor structures in accordance with some embodiments of the present disclosure.

FIG. 2, FIG. 4, FIG. 5, FIG. 7 and FIG. 8 schematically illustrate various semiconductor structures in accordance with other embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Stack of semiconductor elements is one of the commonly used solutions to achieve size miniaturization or other purposes. When bonding a plurality of semiconductor elements onto the same element, the plurality of semiconductor elements are expected to be closely bonded to each other to increase the number of semiconductor elements per unit area or to reduce the area in which a desired number of semiconductor elements are arranged. Unfortunately, in practice, gaps are created between the plurality of semiconductor elements due to process limitations, tolerances, errors, or the like. These gaps need to be filled with gap-filling material to facilitate the formation or disposition of other elements subsequently formed thereon. However, as the thermal conductivity of the gap-filling material is generally worse than those of the semiconductor elements, the overall heat dissipation effect is reduced, and thermal management is difficult to be well controlled. As a result, stack of semiconductor elements can be severely affected by thermal problems, and the design flexibility for stack of semiconductor elements is constrained due to hot spot issues.

The present disclosure is related to a semiconductor structure and a manufacturing method thereof. In some embodiments, a heat dissipation element having higher thermal conductivity than that of the gap-filling material is added into the stack of semiconductor elements to replace a portion of the gap-filling material so as to increase heat dissipation paths. Accordingly, heat dissipation performance, thermal management, thermal problems, and/or the design flexibility for stack of semiconductor elements can be improved.

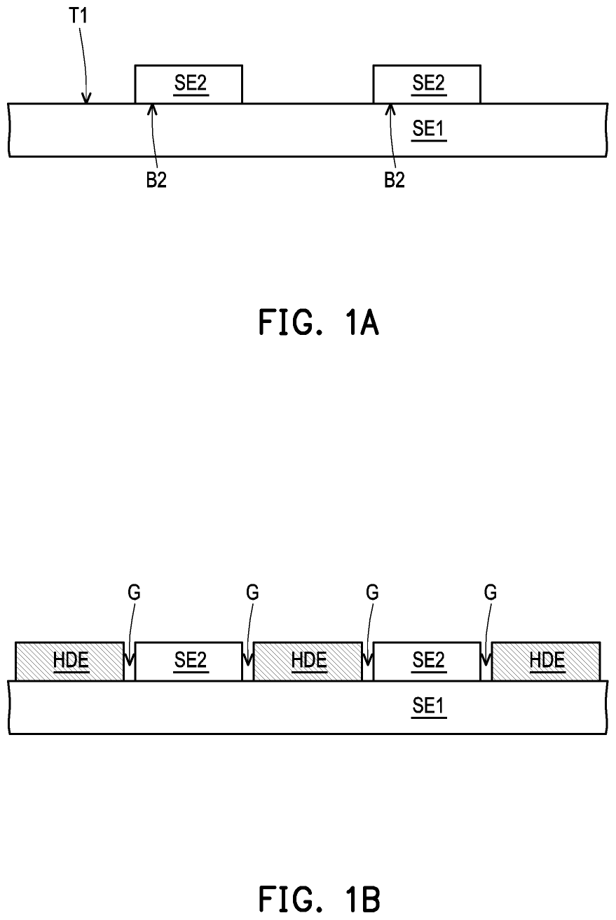

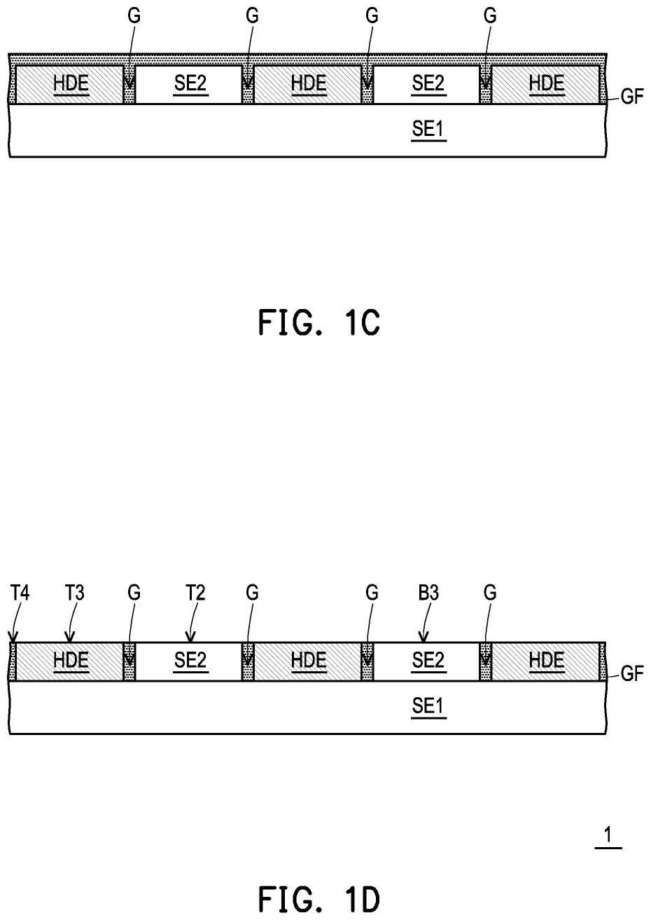

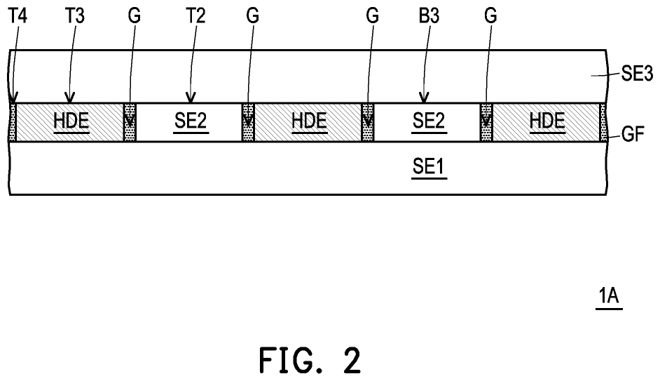

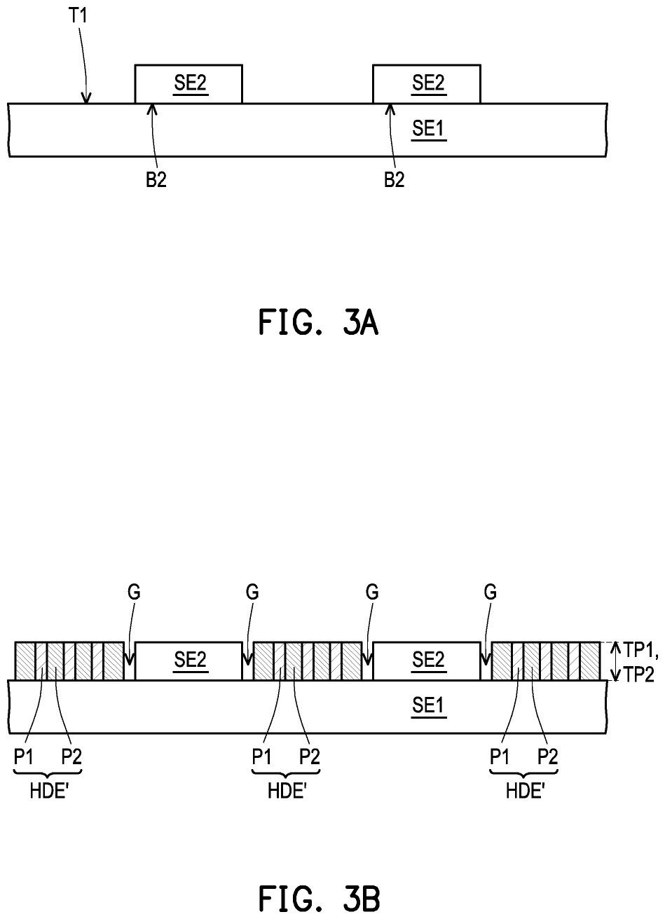

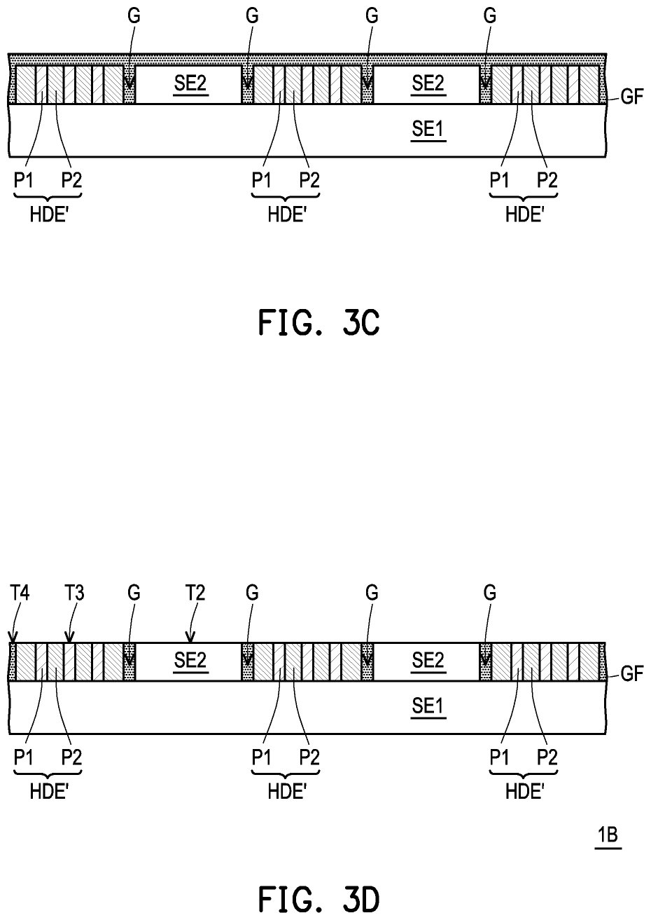

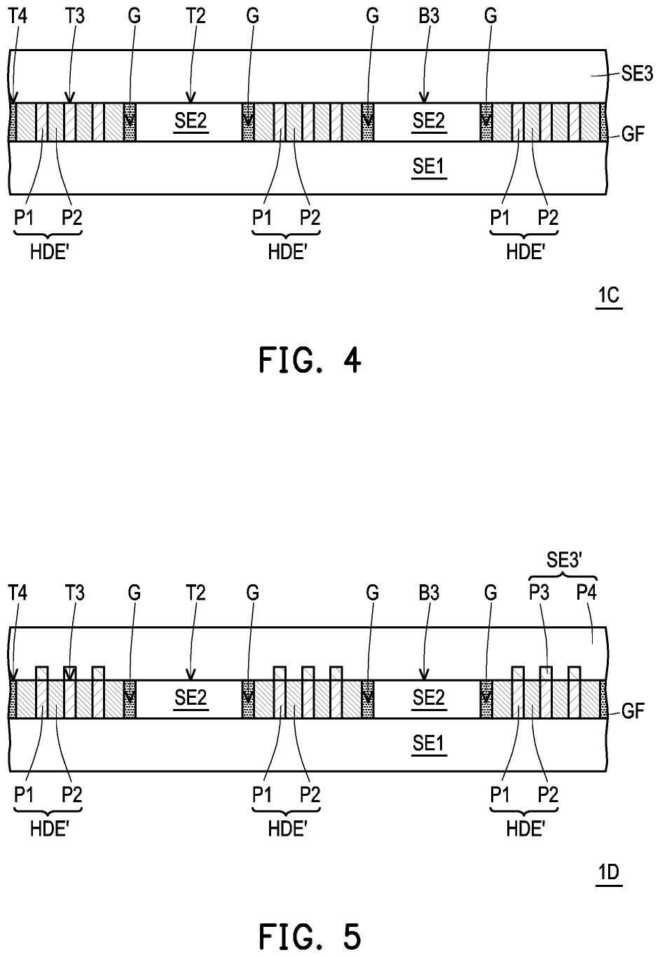

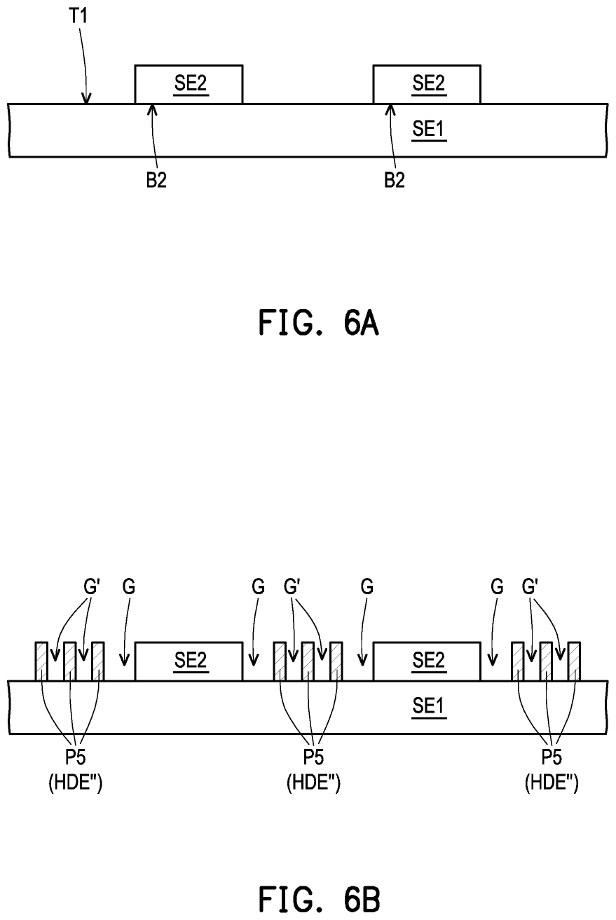

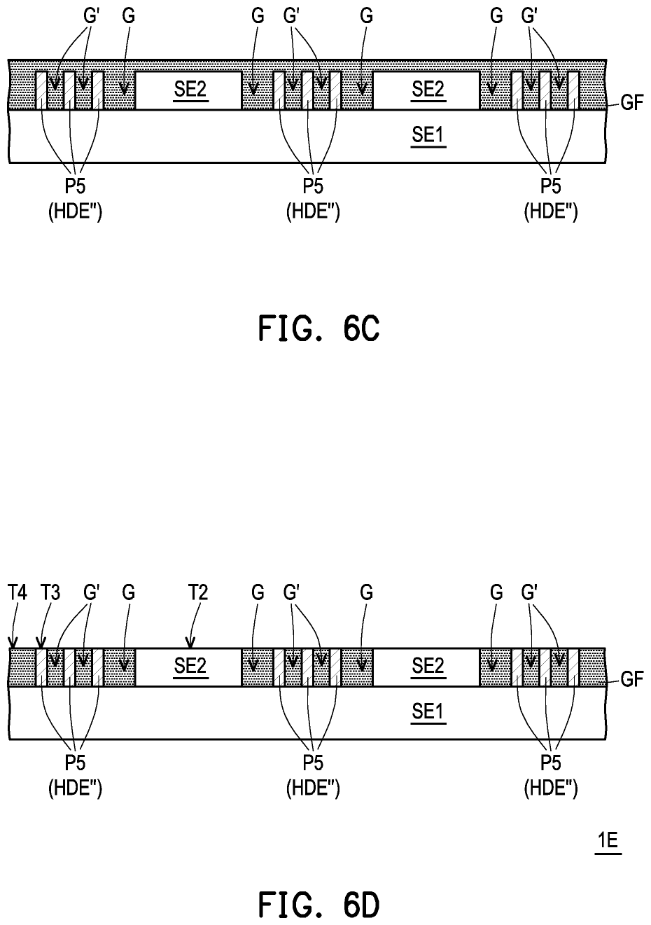

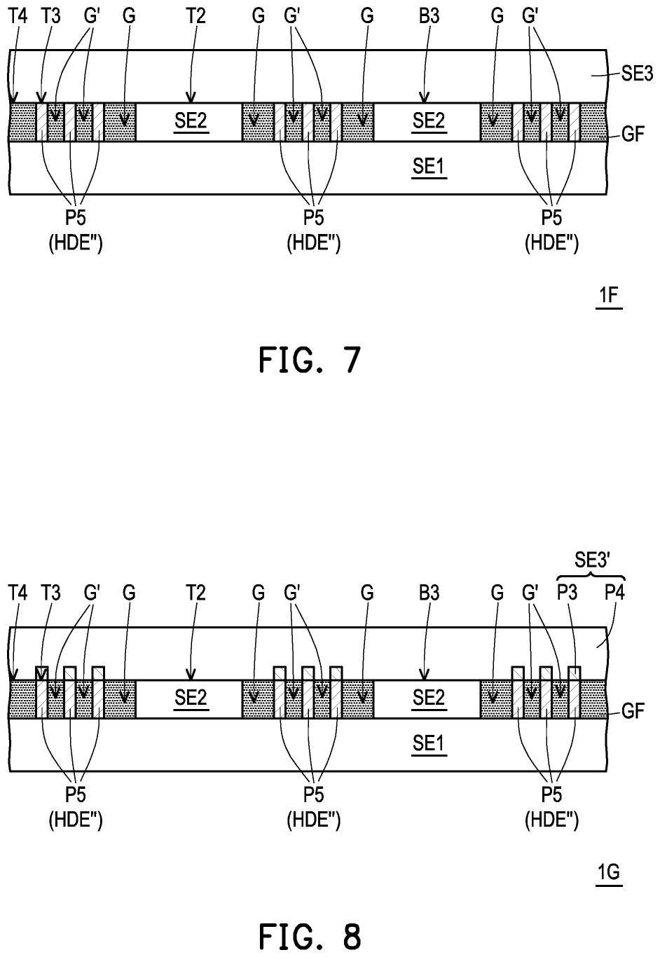

FIG. 1A through FIG. 1D, FIG. 3A through FIG. 3D and FIG. 6A through FIG. 6D schematically illustrate process flows for manufacturing various semiconductor structures in accordance with some embodiments of the present disclosure. FIG. 2, FIG. 4, FIG. 5, FIG. 7 and FIG. 8 schematically illustrate various semiconductor structures in accordance with other embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

Referring to FIG. 1A through FIG. 1D, a manufacturing method of a semiconductor structure 1 in accordance with some embodiments of the present disclosure is provided. The manufacturing method may include: bonding a second semiconductor element SE2 on a first semiconductor element SE1 (e.g., refer to FIG. 1A); bonding a heat dissipation element HDE on the first semiconductor element SE1, wherein the heat dissipation element HDE is spaced apart from the second semiconductor element SE2 by a gap G (e.g., refer to FIG. 1B); forming a gap-filling material GF to fill the gap G between the second semiconductor element SE2 and the heat dissipation element (e.g., refer to FIG. 1C); and planarizing the gap-filling material (e.g., refer to FIG. 1D).

Specifically, as shown in FIG. 1A, bonding the second semiconductor element SE2 on the first semiconductor element SE1 may include disposing the second semiconductor element SE2 on the first semiconductor element SE1 by a pick-and-place process. In FIG. 1A, two second semiconductor element SE2 are presented for illustrative purposes; however, the number of the second semiconductor elements SE2 may be altered according to needs.

The first semiconductor element SE1 may include any kind of wafer form or chip form semiconductor element. For example, the first semiconductor element SE1 may be an interposer formed based on a semiconductor substrate (e.g., a silicon substrate), with through-silicon vias formed in the semiconductor substrate to interconnect the features formed on the opposite sides of the interposer, but is not limited thereto. Alternatively, the first semiconductor element SE1 may be a silicon-substrate-free interposer or a Si-less interposer, wherein the silicon substrate is replaced by dielectric layers, and stacked vias and through-dielectric vias are formed in dielectric layers to replace through-silicon vias. In some embodiments, the first semiconductor element SE1 is a bulk substrate (e.g., a silicon substrate), a printed circuit board (PCB), a printed wiring board, a package substrate, additional semiconductor package, or other semiconductor element that is capable of carrying the semiconductor elements, providing mechanical support or serving as a heat spreader.

In some embodiments, the first semiconductor element SE1 is a semiconductor bulk wafer having plural semiconductor chips therein. In some embodiments, the first semiconductor element SE1 is a monocrystalline semiconductor substrate such as a silicon substrate, a silicon-on-insulator (SOI) substrate, silicon-germanium on insulator (SGOI) or a germanium-on-insulator (GOI) substrate. In some embodiments, the first semiconductor element SE1 includes a semiconductor substrate made of semiconductor materials, such as semiconductor materials of the groups III-V of the periodic table. In some embodiments, the semiconductor substrate includes elementary semiconductor materials such as silicon or germanium, compound semiconductor materials such as silicon carbide, gallium arsenide, indium arsenide, or indium phosphide or alloy semiconductor materials such as silicon germanium, silicon germanium carbide, gallium arsenide phosphide, or gallium indium phosphide.

In certain embodiments, the first semiconductor element SE1 is a reconstructed wafer including a plurality of dies molded in a molding compound. In some embodiments, the first semiconductor element SE1 includes a bonding film (not shown), a plurality of contact pads (not shown) embedded in the bonding film and conductive wirings (not shown) including metal lines, vias and pads for electrical connection and interconnection. It is understood that the first semiconductor element SE1 may further include other conductive elements or layers, doped regions or other semiconductor components, such as active components (e.g., transistors, diodes or the like) and/or passive components (e.g., resistors, capacitors, inductors, or the like) formed therein. In some embodiments, the material of the conductive wirings includes copper or copper alloys. In certain embodiments, the contact pads include metallic pads of aluminum, copper, alloys thereof or other suitable metallic material. In some embodiments, the material of the bonding film includes silicon oxide, silicon nitride, undoped silicate glass material or a suitable dielectric material. In some embodiment, the bonding film is formed through performing a chemical vapor deposition (CVD) process such as low-pressure CVD (LPCVD), plasma enhanced CVD (PECVD), and high-density plasma CVD (HDPCVD). The embodiments are intended for illustration purposes but not intended to limit the scope of the present disclosure.

The second semiconductor elements SE2 may include semiconductor dies, but other kinds of semiconductor elements are within the contemplated scope of the disclosure. The semiconductor die may include memory, flash, power chip, power module, converter, sensor, logic die and so on that can work in conjunction with other semiconductor elements in order to provide a desired functionality to the user. In some embodiments, the second semiconductor elements SE2 include digital dies, analog dies, mixed signal dies, such as application-specific integrated circuit (ASIC) dies, logic dies, sensor dies, other kinds of integrated circuit dies or a combination of the above, but is not limited thereto.

In some embodiments, the second semiconductor elements SE2 are integrated circuit dies, each of which includes a semiconductor substrate (not shown), an interconnection structure (not shown) formed on the semiconductor substrate, a passivation layer (not shown) formed on the interconnection structure, a plurality of conductive pads (not shown) formed on the passivation layer and electrically connected to the interconnection structure, a post passivation layer (not shown) covering the passivation layer and the conductive pads, and a plurality of conductive connectors (not shown) formed on the post passivation layer and electrically connected to the conductive pads.

The semiconductor substrate may be a silicon substrate including active components (e.g., diodes, transistors or the like) and passive components (e.g., resistors, capacitors, inductors or the like) formed therein. The interconnection structure may include a plurality of interconnect wiring layers and a plurality of dielectric layers stacked alternately. The passivation layer covers the interconnection structure and includes a plurality of contact openings such that the topmost interconnect wiring layers of the interconnection structure are exposed through the contact openings of the passivation layer. In some embodiments, the passivation layer is a silicon oxide layer, a silicon nitride layer, a silicon oxy-nitride layer or a dielectric layer formed by other suitable dielectric materials. The conductive pads are formed in the contact openings of the passivation layer and electrically connected to the topmost interconnect wiring layers of the interconnection structure through the contact opening of the passivation layer. In some embodiments, the conductive pads are aluminum pads, copper pads or other suitable metal pads. The post passivation layer may include a plurality of contact openings such that the conductive pads are partially exposed by the contact openings of the post passivation layer. In some embodiments, the post passivation layer is a polyimide (PI) layer, a polybenzoxazole (PBO) layer, or a dielectric layer formed by other suitable polymers. The conductive connectors are formed in the contact openings of the post passivation layer and electrically connected to the conductive pads through the contact opening of the post passivation layer. The integrated circuit die may be electrically connected to other semiconductor elements through the conductive connectors. In some embodiments, the conductive connectors are plated copper connectors, copper alloy connectors or other suitable conductive connectors. In some embodiments, top surfaces of the conductive connectors are substantially level with a top surface of the post passivation layer.

In some embodiments, the surface where the conductive connectors are distributed on is referred to as an active surface of the integrated circuit die, and the surface opposite to the active surface of the integrated circuit die is referred to as a rear surface of the integrated circuit die.

In some embodiments, the second semiconductor element SE2 may be bonded on the first semiconductor element SE1 through a direct bonding manner, such as a fusion bonding manner, a hybrid bonding manner, an anodic bonding manner or other direct bonding manner that is chosen according to the material type of the surfaces to be bonded, but is not limited thereto.

For example, when the second semiconductor elements SE2 are bonded to the first semiconductor element SE1 for electrical connection (e.g., when the second semiconductor elements SE2 are integrated circuit dies and the first semiconductor element SE1 is an interposer, a reconstructed wafer or etc.), the bottom surfaces B2 of the second semiconductor elements SE2 may be active surfaces, and the bottom surfaces B2 may be bonded to the top surface T1 of the first semiconductor element SE1 through the hybrid bonding manner. For example, the contact pads (or conductive connectors) of the first semiconductor element SE1 and the second semiconductor elements SE2 are bonded to each other via metal-to-metal bonding, while the bonding films (or post passivation layer) of the first semiconductor element SE1 and the second semiconductor elements SE2 are bonded to each other via dielectric-to-dielectric fusion bonding. In one embodiments, during the bonding process, a low temperature heating process at a temperature of about 100° C. to about 200° C. is performed to heat and bond the dielectric bonding films, and a high temperature heating process is performed at a temperature of about 200° C. to about 300° C. to heat the metallic pads such that the metallic pads are bonded and the dielectric bonding films are cured and adhered to each other.

On the other hand, when the second semiconductor elements SE2 are bonded to the first semiconductor element SE1 for mechanical support (e.g., when the second semiconductor elements SE2 are integrated circuit dies and the first semiconductor element SE1 is a bulk substrate), the bottom surfaces B2 of the second semiconductor elements SE2 may be rear surfaces, and the bottom surfaces B2 may be bonded to the top surface T1 of the first semiconductor element SE1 through the anodic bonding manner. In some alternative embodiments, the bottom surfaces B2 is bonded to the top surface T1 of the first semiconductor element SE1 through the fusion bonding manner, and dielectric layers (not shown) are respectively formed on the bottom surfaces B2 of the second semiconductor elements SE2 and the top surface T1 of the first semiconductor element SE1 prior to bonding the second semiconductor elements SE2 to the first semiconductor element SE1. The dielectric layers may include silicon oxide layers, silicon nitride layers, silicon oxy-nitride layers or dielectric layers formed by other suitable dielectric materials. In other alternative embodiments, the second semiconductor elements SE2 are bonded to the first semiconductor element SE1 through thermal interface material (TIM) adhesion, and thermal interface materials (not shown) are respectively formed on the bottom surfaces B2 of the second semiconductor elements SE2 and the top surface T1 of the first semiconductor element SE1 prior to bonding the second semiconductor elements SE2 to the first semiconductor element SE1. The thermal interface materials may be adhesives having a high thermal conductivity, for example, higher than about 1 W/k*m or higher than about 5 W/k*m, but not limited thereto.

As shown in FIG. 1B, bonding the heat dissipation element HDE on the first semiconductor element SE1 may include disposing the heat dissipation element HDE on the first semiconductor element SE1 by a pick-and-place process. In FIG. 1B, three heat dissipation elements HDE are presented for illustrative purposes, wherein each second semiconductor element SE2 is disposed between two adjacent heat dissipation elements HDE and one of the three heat dissipation elements HDE is disposed between two adjacent second semiconductor elements SE2; however, the number of the heat dissipation elements HDE and/or the relative disposition between the heat dissipation elements HDE and the second semiconductor elements SE2 may be altered according to needs. For example, more than one heat dissipation elements HDE may be disposed between two adjacent second semiconductor elements SE2, but not limited thereto.

The heat dissipation elements HDE may have a higher thermal conductivity than the subsequently formed gap-filling material GF to improve thermal performance of the stack of semiconductor elements. In some embodiments, the thermal conductivity of the heat dissipation elements HDE is larger than or equal to 100 W/k*m, but not limited thereto. In some embodiments, each of the heat dissipation elements HDE is a block of a single material with high thermal conductivity. For example, material of the block may include boron nitride, boron carbide, silicon carbide, aluminum nitride, silicon nitride, diamond, diamond-like carbon, a carbon nanotube, a carbon nano wire, graphite, graphene, silicon, beryllia, aluminum oxide, zinc oxide, gold, silver, copper, aluminum, magnesium, tungsten, molybdenum, other metal material or alloys of the above, but not limited thereto.

In some embodiments, the heat dissipation elements HDE may be bonded on the first semiconductor element SE1 through a direct bonding manner, such as a fusion bonding manner, a hybrid bonding manner, an anodic bonding manner or other direct bonding manner that is chosen according to the material type of the surfaces to be bonded, but is not limited thereto.

Each heat dissipation element HDE is spaced apart from the adjacent second semiconductor element SE2 by a gap G. In FIG. 1B, four gaps G are presented for illustrative purposes; however, the number of the gaps G may be altered according to actual design, and the dimensions of the gaps G may vary due to process variation, errors or other factors.

As shown in FIG. 1C, forming the gap-filling material GF to fill the gaps G between the second semiconductor elements SE2 and the heat dissipation elements HDE may include forming the gap-filling material GF over the first semiconductor element SE1, covering the second semiconductor elements SE2 and the heat dissipation elements HDE and filling up the gaps G. In some embodiments, the gap-filling material GF includes a molding compound, a molding underfill, a resin (such as an epoxy resin), an oxide filling material (such as silicon oxide or silicate glass materials) or other dielectric materials.

As shown in FIG. 1D, planarizing the gap-filling material GF may include remove the extra gap-filling material GF, so that a top surface T4 of the gap-filling material GF is coplanar and level with top surfaces T2 of the second semiconductor elements SE2 and top surfaces T3 of the heat dissipation elements HDE. In some embodiments, the planarization process includes one or more of a mechanical grinding process, a chemical mechanical polishing (CMP) process or a combination thereof.

After the planarization process, a semiconductor structure 1 in accordance with some embodiments of the present disclosure is preliminarily formed. The semiconductor structure 1 may include the first semiconductor element SE1, the second semiconductor element(s) SE2 on the first semiconductor element SE1, the heat dissipation element(s) HDE on the first semiconductor element SE1 and spaced apart from the second semiconductor element SE2 by a gap G and the gap-filling material GF filled in the gap G between the second semiconductor element SE2 and the heat dissipation element HDE.

Note that, as shown in FIG. 1D, two second semiconductor elements SE2 and three heat dissipation elements HDE are presented for illustrative purposes; however, the number of the second semiconductor elements SE2 or the heat dissipation elements HDE and/or arrangement of the second semiconductor elements SE2 and the heat dissipation elements HDE may be altered according to needs, the disclosure is not limited thereto. For example, more than two second semiconductor elements SE2 may be arranged in an array, and the heat dissipation elements HDE may be arranged around the periphery of the second semiconductor elements SE2, but is not limited thereto.

The heat dissipation element(s) HDE on the first semiconductor element SE1 helps to increase heat dissipation paths. Accordingly, heat dissipation performance, thermal management, thermal problems, and/or the design flexibility for stack of semiconductor elements can be improved.

Referring to FIG. 2, a semiconductor structure 1A in accordance with some embodiments of the present disclosure is provided. The semiconductor structure 1A further includes a third semiconductor element SE3 in addition to the first semiconductor element SE1, the second semiconductor elements SE2, the heat dissipation elements HDE and the gap-filling material GF. The third semiconductor element SE3 is on the second semiconductor elements SE2, the heat dissipation elements HDE and the gap-filling material GF.

The third semiconductor element SE3 may be any kind of wafer form or chip form semiconductor element. For example, the third semiconductor element SE3 may be a bulk substrate (e.g., a silicon substrate) configured to provide mechanical support or serve as a heat spreader, but is not limited thereto.

In some embodiments, a bottom surface B3 of the third semiconductor element SE3 is bonded to the top surfaces T2 of the second semiconductor elements SE2, the top surfaces T3 of the heat dissipation elements HDE and the top surface T4 of the gap-filling material GF through a direct bonding manner, such as a fusion bonding manner, a hybrid bonding manner, an anodic bonding or other direct bonding manner that is chosen according to the material type of the surfaces to be bonded, but is not limited thereto. In some alternative embodiments, the third semiconductor element SE3 is bonded to the second semiconductor elements SE2, the heat dissipation elements HDE and the gap-filling material GF through thermal interface material adhesion. The thermal interface material is an adhesive having a high thermal conductivity, for example, higher than about 1 W/k*m or higher than about 5 W/k*m, but is not limited thereto.

A manufacturing method of the semiconductor structure 1A further includes bonding the third semiconductor element SE3 on the second semiconductor elements SE2, the heat dissipation elements HDE and the gap-filling material GF in addition to the steps shown in FIG. 1A through FIG. 1D, and the bonding of the third semiconductor element SE3 may be subsequent to the step shown in FIG. 1D.

Referring to FIG. 3A through FIG. 3D, a manufacturing method of a semiconductor structure 1B in accordance with some embodiments of the present disclosure is provided. In the semiconductor structure 1B, each heat dissipation element HDE′ is, for example, a block including a first portion P1 and a second portion P2 surrounding the first portion P1, and a thermal conductivity of the first portion P1 is higher than that of the second portion P2. In FIG. 3B through FIG. 3D, each heat dissipation element HDE′ with three first portions P1 are presented for illustrative purposes; however, the number of the first portions P1 in each heat dissipation element HDE′ may be altered according to needs.

In some embodiments, a manufacturing method of the heat dissipation element HDE′ may include forming via openings in a bulk material mass by, for example, etching, milling, machining, laser drilling, or a combination thereof; and forming first portion material over the bulk material mass and filling the via openings by, for example, an electro-chemical plating process, CVD, ALD, physical vapor deposition (PVD), combinations thereof or other semiconductor processes. The manufacturing method of the heat dissipation element HDE′ may further include a planarization process to remove extra first portion material outside the via openings to form the heat dissipation element HDE′ with the first portion P1 and the second portion P2 having the same thickness, e.g., a thickness TP1 of the first portion P1 is the same as a thickness TP2 of the second portion P2. In some embodiments, materials of the first portion P1 and the second portion P2 may be selected from boron nitride, boron carbide, silicon carbide, aluminum nitride, silicon nitride, diamond, diamond-like carbon, a carbon nanotube, a carbon nano wire, graphite, graphene, silicon, beryllia, aluminum oxide, zinc oxide, gold, silver, copper, aluminum, magnesium, tungsten, molybdenum, other metal material and alloys of the above, but not limited thereto.

The first portion P1 may be made of a material with high thermal conductivity but relatively high cost, while the second portion P2 may be made of a material with lower thermal conductivity and lower cost than the first portion P1. By using composite materials to form the heat dissipation element HDE′, the amount of relatively expensive material can be reduced while increasing the heat dissipation paths.

In some embodiments, the heat dissipation elements HDE′ are formed and then the heat dissipation elements HDE′ are bonded on the first semiconductor element SE1 through a direct bonding manner described above or through thermal interface material (TIM) adhesion, but not limited thereto. In some alternative embodiments, the heat dissipation elements HDE′ are formed directly on the first semiconductor element SE1 through semiconductor processes. In addition, the gap-filling material GF may be in contact with the second portion P2 of the heat dissipation element HDE′, as shown in FIG. 3C or FIG. 3D.

Referring to FIG. 4, a semiconductor structure 1C in accordance with some embodiments of the present disclosure is provided. The semiconductor structure 1C further includes the third semiconductor element SE3 in addition to the first semiconductor element SE1, the second semiconductor elements SE2, the heat dissipation elements HDE′ and the gap-filling material GF. The third semiconductor element SE3 is on the second semiconductor elements SE2, the heat dissipation elements HDE′ and the gap-filling material GF. The third semiconductor element SE3 in FIG. 4 is similar to the third semiconductor element SE3 in FIG. 2, so the detailed descriptions are not repeated for brevity.

Referring to FIG. 5, a semiconductor structure 1D in accordance with some embodiments of the present disclosure is provided. In the semiconductor structure 1D, a third semiconductor element SE3′ is bonded on the second semiconductor elements SE2, the heat dissipation elements HDE and the gap-filling material GF, wherein the third semiconductor element SE3′ includes a third portion P3 and a fourth portion P4 surrounding and covering the third portion P3, and a thermal conductivity of the third portion P3 is higher than that of the fourth portion P4.

Specifically, the third portion P3 may be inlaid in the fourth portion P4. For example, the third semiconductor element SE3′ may be prefabricated through semiconductor manufacturing processes. In some embodiments, the third semiconductor element SE3′ is formed by forming the third portion P3 in the fourth portion P4, and the top view of the third portion P3 is in the shape of a crisscross pattern (or grid pattern); however, the top view of the third portion P3 may be in any shape. In some embodiments, a bulk semiconductor material mass (not shown) such as a silicon wafer, a germanium wafer or a SOI wafer is provided as the fourth portion P4. In some embodiments, the formation of the third portion P3 includes patterning the bulk semiconductor material mass to form interconnected shallow trenches as openings for the later formed grid pattern by performing one or more etching process(es) and forming a thermal conductive material (e.g., metal material) over the semiconductor material mass and filling the trench openings. The formation of the third portion P3 may further includes performing a planarization process to remove extra metal material. In some embodiments, for the third portion P3, the metal material includes copper, aluminum, cobalt, tungsten, titanium, alloys, or combinations thereof, but not limited thereto. In some alternative embodiments, the third portion P3 can be made from the material of the heat dissipation element HDE described above.

In some embodiments, the thickness of the third portion P3 is smaller than the thickness of the fourth portion P4. That is, the third portion P3 is partially exposed from the bottom surface (e.g., the bottom surface B3) of the fourth portion P4 of the third semiconductor element SE3′.

In some embodiments, the third semiconductor element SE3′ is bonded on the second semiconductor elements SE2, the heat dissipation elements HDE and the gap-filling material GF through a direct bonding manner, such as a fusion bonding manner, a hybrid bonding manner, an anodic bonding manner or other direct bonding manner that is chosen according to the material type of the surfaces to be bonded, but is not limited thereto. In some embodiments, the third portion P3 is bonded to the first portion P1, and the fourth portion P4 is bonded to the second portion P2. In some embodiments, the third portion P3 is in contact with the first portion P1, and the fourth portion P4 is in contact with the second portion P2. In FIG. 5, the third portion P3 having the number and position corresponding to the first portion P1 is presented for illustrative purposes; however, the design parameters such as the pattern, position and quantity of the third portion P3 can be adjusted according to actual needs. For example, although not shown, the third portion P3 may further locate on the second semiconductor elements SE2, but not limited thereto.

Referring to FIG. 6A through FIG. 6D, a manufacturing method of a semiconductor structure 1E in accordance with some embodiments of the present disclosure is provided. The manufacturing method may include: bonding a second semiconductor element SE2 on a first semiconductor element SE1 (e.g., refer to FIG. 6A); forming a plurality of heat dissipation pillars P5 on the first semiconductor element SE1 and around the second semiconductor element SE2 (e.g., refer to FIG. 6B); forming a gap-filling material GF to fill gaps G between the second semiconductor element SE2 and the plurality of heat dissipation pillars P5 and gaps G′ between any two adjacent heat dissipation pillars P5 among the plurality of heat dissipation pillars P5 (e.g., refer to FIG. 6C); and planarizing the gap-filling material GF (e.g., refer to FIG. 6D).

The step shown in FIG. 6A is similar to the step shown in FIG. 1A, so the detailed descriptions are not repeated for brevity.

Referring to FIG. 6B, the plurality of heat dissipation pillars P5 may be formed on the first semiconductor element SE1 and around the second semiconductor elements SE2 through a photolithography process, a plating process and a photoresist stripping processes. For example, a mask pattern (not shown) covering the first semiconductor element SE1 and the second semiconductor elements SE2 with openings exposing regions where the plurality of heat dissipation pillars P5 are to be formed is formed. Thereafter, a heat dissipation material (not shown; e.g., a metallic material) is filled into the openings by electroplating or deposition. Then, the mask pattern is removed to obtain the plurality of heat dissipation pillars P5. However, the disclosure is not limited thereto, and other suitable methods may be utilized in the formation of the plurality of heat dissipation pillars P5. In some embodiments, the material of the plurality of heat dissipation pillars P5 includes a metal material such as copper, copper alloys, the like or the material of the heat dissipation element HDE described above, but not limited thereto. It should be noted that each heat dissipation element HDE″ with three heat dissipation pillars P5 are presented in FIG. 6B through FIG. 6D for illustrative purposes; however, more or fewer heat dissipation pillars may be formed in some alternative embodiments. The number of the heat dissipation pillars may be selected based on design and production requirements.

Referring to FIG. 6C, the gap-filling material GF is formed over the first semiconductor element SE1 to at least encapsulate the second semiconductor elements SE2 and the heat dissipation elements HDE″ and fill the gaps G between the second semiconductor elements SE2 and the plurality of heat dissipation pillars P5 and the gaps G′ between any two adjacent heat dissipation pillars P5 among the plurality of heat dissipation pillars P5. In some embodiments, not only the second semiconductor elements SE2 but also the heat dissipation elements HDE″ are fully covered and not revealed by the gap-filling material GF. In some embodiments, the gap-filling material GF is formed by an over-molding process. In some embodiments, the gap-filling material GF is formed by a compression molding process.

Referring to FIG. 6D, the gap-filling material GF is partially removed by a planarization process until the second semiconductor elements SE2 and the plurality of heat dissipation pillars P5 are exposed. In some embodiments, upper portions of the second semiconductor elements SE2 and the plurality of heat dissipation pillars P5 may be removed during the planarization process. Planarization of the gap-filling material GF may produce a gap-filling layer located over the first semiconductor element SE1 to surround the second semiconductor elements SE2 and the plurality of heat dissipation pillars P5, but the top surfaces T2 of the second semiconductor elements SE2 and the top surfaces T3 of the plurality of heat dissipation pillars P5 are exposed from the gap-filling layer. In some embodiments, the planarization of the gap-filling material GF includes performing a mechanical grinding process and/or a chemical mechanical polishing (CMP) process. After the grinding process or the polishing process, the top surfaces T2 of the second semiconductor elements SE2 and the top surfaces T3 of the plurality of heat dissipation pillars P5 may be substantially coplanar and level with the top surface T4 of the gap-filling material GF.

After the planarization process, a semiconductor structure 1E in accordance with some embodiments of the present disclosure is preliminarily formed. The semiconductor structure 1E may include the first semiconductor element SE1, the second semiconductor element(s) SE2 on the first semiconductor element SE1, the heat dissipation element(s) HDE″ on the first semiconductor element SE1 and spaced apart from the second semiconductor element SE2 by a gap G and the gap-filling material GF filled in the gap G between the second semiconductor element SE2 and the heat dissipation element HDE, wherein each the heat dissipation element HDE″ includes a plurality of heat dissipation pillars P5 spaced apart from each other, and the gap-filling material GF is further filled in gaps G1 between any two adjacent heat dissipation pillars P5 among the plurality of heat dissipation pillars P5.

Referring to FIG. 7, a semiconductor structure 1F in accordance with some embodiments of the present disclosure is provided. The semiconductor structure 1F further includes the third semiconductor element SE3 in addition to the first semiconductor element SE1, the second semiconductor elements SE2, the heat dissipation elements HDE″ and the gap-filling material GF. The third semiconductor element SE3 is on the second semiconductor elements SE2, the heat dissipation elements HDE″ and the gap-filling material GF. The third semiconductor element SE3 in FIG. 7 is similar to the third semiconductor element SE3 in FIG. 2, so the detailed descriptions are not repeated for brevity.

Referring to FIG. 8, a semiconductor structure 1G in accordance with some embodiments of the present disclosure is provided. The semiconductor structure 1G further includes the third semiconductor element SE3′ in addition to the first semiconductor element SE1, the second semiconductor elements SE2, the heat dissipation elements HDE″ and the gap-filling material GF. The third semiconductor element SE3′ is on the second semiconductor elements SE2, the heat dissipation elements HDE″ and the gap-filling material GF. The third semiconductor element SE3′ in FIG. 8 is similar to the third semiconductor element SE3′ in FIG. 5, so the detailed descriptions are not repeated for brevity.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the present disclosure, a semiconductor structure includes a first semiconductor element, a second semiconductor element, a heat dissipation element and a gap-filling material. The second semiconductor element is on the first semiconductor element. The heat dissipation element is on the first semiconductor element and spaced apart from the second semiconductor element by a gap. The gap-filling material is filled in the gap between the second semiconductor element and the heat dissipation element. In some embodiments, a thermal conductivity of the heat dissipation element is larger than or equal to 100 W/k*m. In some embodiments, a top surface of the gap-filling material is level with a top surface of the second semiconductor element and a top surface of the heat dissipation element. In some embodiments, the semiconductor structure further includes a third semiconductor element on the second semiconductor element, the heat dissipation element and the gap-filling material. In some embodiments, the heat dissipation element is a block of a single material. In some embodiments, the heat dissipation element is a block including a first portion and a second portion surrounding the first portion, and a thermal conductivity of the first portion is higher than that of the second portion. In some embodiments, the gap-filling material is in contact with the second portion of the heat dissipation element. In some embodiments, the semiconductor structure further includes a third semiconductor element bonded on the second semiconductor element, the heat dissipation element and the gap-filling material, wherein the third semiconductor element comprises a third portion and a fourth portion surrounding and covering the third portion, and a thermal conductivity of the third portion is higher than that of the fourth portion. In some embodiments, the third portion is bonded to the first portion, and the fourth portion is bonded to the second portion. In some embodiments, the heat dissipation element includes a plurality of heat dissipation pillars spaced apart from each other, and the gap-filling material is further filled in gaps between any two adjacent heat dissipation pillars among the plurality of heat dissipation pillars.

In accordance with some embodiments of the present disclosure, a manufacturing method of a semiconductor structure includes: bonding a second semiconductor element on a first semiconductor element; bonding a heat dissipation element on the first semiconductor element, wherein the heat dissipation element is spaced apart from the second semiconductor element by a gap; forming a gap-filling material to fill the gap between the second semiconductor element and the heat dissipation element; and planarizing the gap-filling material. In some embodiments, the second semiconductor element is bonded on the first semiconductor element through a fusion bond or a hybrid bond. In some embodiments, the heat dissipation element is bonded on the first semiconductor element through a fusion bond or a hybrid bond. In some embodiments, the manufacturing method of the semiconductor structure further includes bonding a third semiconductor element on the second semiconductor element, the heat dissipation element and the gap-filling material. In some embodiments, the third semiconductor element is bonded on the second semiconductor element, the heat dissipation element and the gap-filling material through a fusion bond or a hybrid bond.

In accordance with alternative embodiments of the present disclosure, a manufacturing method of a semiconductor structure includes: bonding a second semiconductor element on a first semiconductor element; forming a plurality of heat dissipation pillars on the first semiconductor element and around the second semiconductor element; forming a gap-filling material to fill gaps between the second semiconductor element and the plurality of heat dissipation pillars and gaps between any two adjacent heat dissipation pillars among the plurality of heat dissipation pillars; and planarizing the gap-filling material. In some embodiments, the second semiconductor element is bonded on the first semiconductor element through a fusion bond or a hybrid bond. In some embodiments, the plurality of heat dissipation pillars are formed on the first semiconductor element through a photolithography process, a plating process and a photoresist stripping processes. In some embodiments, the manufacturing method of the semiconductor structure further includes bonding a third semiconductor element on the second semiconductor element, the plurality of heat dissipation pillars and the gap-filling material. In some embodiments, the third semiconductor element is bonded on the second semiconductor element, the plurality of heat dissipation pillars and the gap-filling material through a fusion bond or a hybrid bond.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor element;
a second semiconductor element on the first semiconductor element;
a heat dissipation element on the first semiconductor element and spaced apart from the second semiconductor element by a gap; and
a gap-filling material filled in the gap between the second semiconductor element and the heat dissipation element.

2. The semiconductor structure according to claim 1, wherein a thermal conductivity of the heat dissipation element is larger than or equal to 100 W/k*m.

3. The semiconductor structure according to claim 1, wherein a top surface of the gap-filling material is level with a top surface of the second semiconductor element and a top surface of the heat dissipation element.

4. The semiconductor structure according to claim 1, further comprising:
a third semiconductor element on the second semiconductor element, the heat dissipation element and the gap-filling material.

5. The semiconductor structure according to claim 1, wherein the heat dissipation element is a block of a single material.

6. The semiconductor structure according to claim 1, wherein the heat dissipation element is a block comprising a first portion and a second portion surrounding the first portion, and a thermal conductivity of the first portion is higher than that of the second portion.

7. The semiconductor structure according to claim 6, wherein the gap-filling material is in contact with the second portion of the heat dissipation element.

8. The semiconductor structure according to claim 6, further comprising:
a third semiconductor element bonded on the second semiconductor element, the heat dissipation element and the gap-filling material, wherein the third semiconductor element comprises a third portion and a fourth portion surrounding and covering the third portion, and a thermal conductivity of the third portion is higher than that of the fourth portion.

9. The semiconductor structure according to claim 8, wherein the third portion is bonded to the first portion, and the fourth portion is bonded to the second portion.

10. The semiconductor structure according to claim 1, wherein the heat dissipation element comprises a plurality of heat dissipation pillars spaced apart from each other, and the gap-filling material is further filled in gaps between any two adjacent heat dissipation pillars among the plurality of heat dissipation pillars.

11. A manufacturing method of a semiconductor structure, comprising:
bonding a second semiconductor element on a first semiconductor element;
bonding a heat dissipation element on the first semiconductor element, wherein the heat dissipation element is spaced apart from the second semiconductor element by a gap;
forming a gap-filling material to fill the gap between the second semiconductor element and the heat dissipation element; and
planarizing the gap-filling material.

12. The manufacturing method of the semiconductor structure according to claim 11, wherein the second semiconductor element is bonded on the first semiconductor element through a fusion bond or a hybrid bond.

13. The manufacturing method of the semiconductor structure according to claim 11, wherein the heat dissipation element is bonded on the first semiconductor element through a fusion bond or a hybrid bond.

14. The manufacturing method of the semiconductor structure according to claim 11, further comprising:
bonding a third semiconductor element on the second semiconductor element, the heat dissipation element and the gap-filling material.

15. The manufacturing method of the semiconductor structure according to claim 14, wherein the third semiconductor element is bonded on the second semiconductor element, the heat dissipation element and the gap-filling material through a fusion bond or a hybrid bond.

16. A manufacturing method of a semiconductor structure, comprising:
bonding a second semiconductor element on a first semiconductor element;
forming a plurality of heat dissipation pillars on the first semiconductor element and around the second semiconductor element;
forming a gap-filling material to fill gaps between the second semiconductor element and the plurality of heat dissipation pillars and gaps between any two adjacent heat dissipation pillars among the plurality of heat dissipation pillars; and
planarizing the gap-filling material.

17. The manufacturing method of the semiconductor structure according to claim 16, wherein the second semiconductor element is bonded on the first semiconductor element through a fusion bond or a hybrid bond.

18. The manufacturing method of the semiconductor structure according to claim 16, wherein the plurality of heat dissipation pillars are formed on the first semiconductor element through a photolithography process, a plating process and a photoresist stripping processes.

19. The manufacturing method of the semiconductor structure according to claim 16, further comprising:
bonding a third semiconductor element on the second semiconductor element, the plurality of heat dissipation pillars and the gap-filling material.

20. The manufacturing method of the semiconductor structure according to claim 19, wherein the third semiconductor element is bonded on the second semiconductor element, the plurality of heat dissipation pillars and the gap-filling material through a fusion bond or a hybrid bond.
